(19) United States
(12) Patent Application Publication
(10) Pub. No.: US 2026/0173947 A1
(43) Pub. Date: Jun. 18, 2026

(54) METHOD FOR MANUFACTURING SEMICONDUCTOR DEVICE, SUBSTRATE, AND SEMICONDUCTOR ELEMENT

(71) Applicant: RESONAC CORPORATION, Minato-ku, Tokyo (JP)

(72) Inventor: Shizu FUKUZUMI, Chiyoda-ku, Tokyo (JP)

(21) Appl. No.: 18/859,557

(22) PCT Filed: Jul. 8, 2022
(86) PCT No.: PCT/JP2022/027100

§ 371 Date: Oct. 24, 2024

(51) Int. Cl. H10W 72/90; H10W 72/00; H10W 72/20; H10W 90/00

(52) U.S. Cl. CPC H10W 72/934; H10W 72/07236; H10W 72/222; H10W 72/856; H10W 90/722; H10W 90/724; H10W 90/732; H10W 90/734

(57) ABSTRACT

A method for manufacturing a semiconductor device includes: layering a semiconductor element, which includes a protruding electrode having a solder layer at a distal end portion of the protruding electrode, on a substrate, the substrate including an electrode pad having a metal protruding portion on a surface of the electrode pad, with a surface of the substrate on which the electrode pad is provided facing a surface of the semiconductor element on which the protruding electrode is provided, such that the solder layer in the semiconductor element and a distal end of the metal protruding portion in the substrate are brought into contact with each other in a state in which a resin film is interposed between the semiconductor element and the substrate; and melting the solder layer by heating to connect the substrate and the semiconductor element.

### TECHNICAL FIELD

The present disclosure relates to a method for manufacturing a semiconductor device, a substrate, and semiconductor element.

### BACKGROUND ART

Conventionally, a wire bonding connection method using a thin metal wire such as a gold wire has been known as a method of mounting a semiconductor element on a substrate. On the other hand, in response to demands for miniaturization, thinning, high functionality, high integration, high speed, or the like of semiconductor devices, a flip-chip connection method (FC connection method) for connecting a semiconductor element and an electrode on a substrate via protruding electrodes called bumps provided on the semiconductor element is spreading. The FC connection method is heavily used in Ball Grid Array (BGA), Chip Size Package (CSP), or the like for connecting a semiconductor element and a substrate. A Chip On Board (COB) type connection method is also encompassed by the FC connection method. The FC connection method is also widely used for a Chip On Chip (COC) type connection method for connecting semiconductor elements (see, for example, Patent Document 1).

In response to demands for further miniaturization, thinning, and higher functionality of semiconductor devices, a chip stack type package and Package On Package (POP), in which layering and multi-staging are carried out by the above-mentioned connection method, have been widely used. A Through-Silicon Via (TSV) method is also being widely used. Such a layering and multi-staging technique three-dimensionally arranges semiconductor elements and the like, and thus can reduce a package area as compared with a method of two-dimensionally arranging semiconductor elements and the like. In particular, the TSV technology is effective for improving the performance of semiconductors, reducing noise, reducing mounting area, and saving power, and is attracting attention as a next-generation semiconductor wiring technology.

In a case in which a semiconductor device is manufactured by the FC connection method, a thermal stress resulting from a difference in thermal expansion coefficient between a semiconductor element and a substrate, or a difference in thermal expansion coefficient between semiconductor elements may concentrate at a connecting portion to cause a connection failure. In order to prevent a connection failure resulting from a difference in thermal expansion coefficient, it is effective to seal a gap between two adjacent circuit members (semiconductor element, substrate, and the like) with an adhesive composition. In particular, since components different in thermal expansion coefficient are often used for a semiconductor element and a substrate, it is demanded to seal a semiconductor device with an adhesive composition to improve thermal shock resistance.

The FC connection method using an adhesive composition can be roughly classified into a Capillary-Flow method and a Pre-Applied method (see, for example, Patent Documents 2 to 6). The Capillary-Flow method is a method in which, after connecting a semiconductor element and a substrate, a liquid adhesive composition is injected into a gap between the semiconductor element and the substrate by a capillary phenomenon. The Pre-Applied method is a method in which a paste or film-like adhesive composition is supplied onto a semiconductor element or a substrate before the semiconductor element and the substrate are connected, and then the semiconductor element and the substrate are connected.

### PRIOR ART DOCUMENTS

### Patent Documents

Patent Document 1: Japanese Patent Application Laid-Open (JP-A) No. 2008-294382
Patent Document 2: Japanese Patent Application Laid-Open (JP-A) No. 2001-223227
Patent Document 3: Japanese Patent Application Laid-Open (JP-A) No. 2002-283098
Patent Document 4: Japanese Patent Application Laid-Open (JP-A) No. 2005-272547
Patent Document 5: Japanese Patent Application Laid-Open (JP-A) No. 2006-169407
Patent Document 6: Japanese Patent Application Laid-Open (JP-A) No. 2006-188573

### SUMMARY OF INVENTION

### Technical Problem

Generally, in manufacturing a semiconductor device in a Pre-Applied method using an adhesive composition (underfill material), an underfill material is provided between a semiconductor element and a substrate, and heat curing of the underfill material is performed. Currently, in this method, provision of an underfill material between a semiconductor element and a substrate and heat curing of the underfill material are performed for each semiconductor device. For this reason, the manufacturing efficiency of a semiconductor device using an underfill material of the current Pre-Applied method is poor, and improvement of the manufacturing efficiency becomes an important issue.

In particular, in the case of using a resin film as an underfill material, the resin film may be bitten between a distal end of a protruding electrode and an electrode on a substrate, which may cause a connection failure between the semiconductor element and the substrate. In order to suppress biting of the resin film, a pressure applied at the time of bonding the semiconductor element and the substrate tends to increase, and a pressurization time also tends to be longer.

With the recent progress in miniaturization of semiconductor devices, pitch narrowing and miniaturization of a protruding electrode have been advanced. For this reason, in a case in which solder connection is performed by reflow after a semiconductor element is temporarily mounted on a substrate, misalignment of a connecting portion due to vibration during reflow as a connecting step and handling of a substrate may occur. In a case in which a semiconductor element is multi-staged by a TSV method, the semiconductor element is very unstable after temporary mounting, so that there is a tendency that misalignment is likely to occur at a connecting portion.

The present disclosure has been made in view of the conventional circumstances above, and an object thereof is to provide a method for manufacturing a semiconductor device capable of suppressing biting of a resin film at the time of connection between a semiconductor element and a substrate or connection between semiconductor elements, and a substrate and a semiconductor element which can be applied to the manufacturing method.

### Solution to Problem

Specific means for achieving the object above are as follows.

<1> A method for manufacturing a semiconductor device, including:
layering a semiconductor element, which includes a protruding electrode having a solder layer at a distal end portion of the protruding electrode, on a substrate, the substrate including an electrode pad having a metal protruding portion on a surface of the electrode pad, with a surface of the substrate on which the electrode pad is provided facing a surface of the semiconductor element on which the protruding electrode is provided, such that the solder layer in the semiconductor element and a distal end of the metal protruding portion in the substrate are brought into contact with each other in a state in which a resin film is interposed between the semiconductor element and the substrate; and
melting the solder layer by heating to connect the substrate and the semiconductor element.

<2> The method for manufacturing a semiconductor element according to <1>, in which:
the semiconductor element layered on the substrate includes an electrode pad having a metal protruding portion on a surface of the electrode pad, the electrode pad being provided on a surface of the semiconductor element at an opposite side from the surface on which the protruding electrode is provided,
a plurality of second semiconductor elements, each including a protruding electrode having a solder layer at a distal end portion of the protruding electrode on one surface side and an electrode pad having a metal protruding portion on a surface of the protruding electrode on another surface side, are layered on the semiconductor element layered on the substrate, by successively layering each of the plurality of second semiconductor elements on the semiconductor element layered on the substrate such that a solder layer in one semiconductor element and a distal end of a metal protruding portion of another semiconductor element are brought into contact with each other in a state in which the resin film is interposed between the one semiconductor element and the other semiconductor element, and
the solder layer is melted by heating to collectively connect the substrate and the plurality of second semiconductor elements.

<3> The method for manufacturing a semiconductor device according to <1> or <2>, in which the solder layer and the distal end of the metal protruding portion are brought into contact with each other with the resin film interposed therebetween while being heated under a condition of a melting temperature of solder configuring the solder layer or lower.

<4> The method for manufacturing a semiconductor device according to any one of <1> to <3>, in which the protruding electrode has a pillar and the solder layer provided at a distal end of the pillar, and a total value of an average height of the pillar and an average height of the metal protruding portion is smaller than an average thickness value of the resin film.

<5> The method for manufacturing a semiconductor device according to <4>, in which the average height of the pillar is 20 μm or less.

<6> The method for manufacturing a semiconductor device according to any one of <1> to <5>, in which the distal end of the metal protruding portion has an acute angle.

<7> The method for manufacturing a semiconductor device according to any one of <1> to <6>, in which the resin film contains a thermosetting resin.

<8> The method for manufacturing a semiconductor device according to <7>, in which the thermosetting resin contains at least one selected from the group consisting of an epoxy resin, a polyamic acid, and a polyhydroxyamide.

<9> The method for manufacturing a semiconductor device according to any one of <1> to <6>, in which the resin film contains a thermoplastic resin.

<10> The method for manufacturing a semiconductor device according to <9>, in which the thermoplastic resin contains at least one selected from the group consisting of polyimide, polyamide, polycarbonate, polyacetal, polyphenylene ether, polybutylene terephthalate, polytetrafluoroethylene, polyphenylene sulfide, polysulfone, polyethersulfone, polyarylate, polyamideimide, polyetherimide, polyether ether ketone, an acrylic resin, a phenoxy resin, polyester, polyurethane, polybenzoxazole, and polybutadiene.

<11> The method for manufacturing a semiconductor device according to any one of <1> to <10>, in which the resin film contains an inorganic filler.

<12> The method for manufacturing a semiconductor device according to <11>, in which a content ratio of the inorganic filler is from 10% by mass to 80% by mass based on a total amount of the resin film.

<13> The method for manufacturing a semiconductor device according to any one of <1> to <12>, in which a viscosity of the resin film at 130° C. is from 500 mPa·s to 4000 mPa·s.

<14> A substrate, including an electrode pad having a metal protruding portion with a distal end having an acute angle on a surface of the electrode pad.

<15> A semiconductor element, including an electrode pad having a metal protruding portion with a distal end having an acute angle on a surface of the electrode pad.

### Advantageous Effects of Invention

According to the present disclosure, it is possible to provide a method for manufacturing a semiconductor device capable of suppressing biting of a resin film at the time of connection between a semiconductor element and a substrate or connection between semiconductor elements, and a substrate and a semiconductor element which can be applied to the manufacturing method.

### BRIEF DESCRIPTION OF DRAWINGS

FIG. 1 is a view for describing a method for manufacturing a semiconductor device according to a first embodiment.

FIG. 2 is a cross-sectional view illustrating a cross-section of a modification of a substrate 10 according to the first embodiment.

FIG. 3 is a view for describing the method for manufacturing a semiconductor device according to the first embodiment.

FIG. 4 is a view for describing the method for manufacturing a semiconductor device according to the first embodiment.

FIG. 5 is a view for describing a method for manufacturing a semiconductor device according to a second embodiment.

FIG. 6 is a view for describing the method for manufacturing a semiconductor device according to the second embodiment.

FIG. 7 is a view for describing the method for manufacturing a semiconductor device according to the second embodiment.

### DESCRIPTION OF EMBODIMENTS

The embodiments of the present disclosure will be described in detail below. However, the present disclosure is not limited to the following embodiments. In the following embodiments, constituent elements thereof (including elemental steps and the like) are not essential unless otherwise specified. The same applies to numerical values and their ranges, and does not limit the present disclosure.

In present disclosure, the term “step” encompasses not only a step that is independent from other steps, but also encompasses a step that is not clearly distinguishable from other steps, as long as the purpose of the step is achieved.

In the present disclosure, a numerical range indicated using “to” includes the numerical values written before and after “to” as the minimum and maximum values, respectively.

In a numerical range described stepwise in present disclosure, the upper limit or lower limit described in the numerical range may be replaced with an upper limit or lower limit of another numerical range described stepwise.

In the present disclosure, each component may contain multiple types of substances corresponding to the component. In the case where multiple types of substances corresponding to a component are present in a composition, a content ratio or a content of the component means a total content ratio or a total content of the multiple types of substances present in the composition, unless otherwise specified.

In the present disclosure, particles corresponding to each component may include multiple types of particles. When multiple types of particles corresponding to a component are present in a composition, a particle diameter of the component means a value for a mixture of the multiple types of particles present in the composition, unless otherwise specified.

In the present disclosure, the term “layer” or “film” encompasses not only a case where a layer or film is formed in an entire region when observing the region where the layer or film is present, but also encompasses a case where a layer or film is formed only in a part of the region.

In the present disclosure, the term “layering” refers to stacking layers, and two or more layers may be bonded to each other, or two or more layers may be removable from each other.

In the present disclosure, an average thickness of a layer or film is a value given as an arithmetic mean value of thicknesses measured at five points of the target layer or film.

A thickness of a layer or film can be measured using a micrometer or the like. In the present disclosure, in a case where a thickness of a layer or film can be directly measured, the thickness is measured using a micrometer. On the other hand, in a case of measuring a thickness of one layer or a total thickness of a plurality of layers, the thickness may be measured by observing a cross section of the measurement target using an electron microscope.

### <Method for Manufacturing Semiconductor Device>

The method for manufacturing a semiconductor device of the present disclosure includes: layering (hereinafter, sometimes referred to as a contact step) a semiconductor element, which includes a protruding electrode having a solder layer at a distal end portion of the protruding electrode, on a substrate, the substrate including an electrode pad having a metal protruding portion on a surface of the electrode pad, with a surface of the substrate on which the electrode pad is provided facing a surface of the semiconductor element on which the protruding electrode is provided, such that the solder layer in the semiconductor element and a distal end of the metal protruding portion in the substrate are brought into contact with each other in a state in which a resin film is interposed between the semiconductor element and the substrate; and melting (hereinafter, sometimes referred to as a connecting step) the solder layer by heating to connect the substrate and the semiconductor element.

According to the method for manufacturing a semiconductor device of the present disclosure, biting of the resin film at the time of connection between the semiconductor element and the substrate or connection between the semiconductor elements can be suppressed. The reason is not clear, but is presumed as follows.

In the method for manufacturing a semiconductor device of the present disclosure, in the contact step, a semiconductor element including a protruding electrode having a solder layer at a distal end portion of the protruding electrode, and a substrate including an electrode pad having a metal protruding portion on a surface of the electrode pad are used. Since the metal protruding portion is present on the surface of the electrode pad provided on the substrate, in a case in which the solder layer provided at the distal end of the protruding electrode in the semiconductor element and the distal end of the metal protruding portion in the substrate are brought into contact with each other, the distal end of the metal protruding portion comes into contact with the solder layer while pushing away the resin film. Therefore, it is presumed that the resin film is less likely to be bitten between the protruding electrode provided on the semiconductor element and the electrode pad provided on the substrate. In a case in which the semiconductor elements are connected to each other, it is presumed that the resin film is less likely to be bitten between the protruding electrode and the electrode pad for the same reason.

The resin film is less likely to be bitten between the protruding electrode and the electrode pad, so that there is a tendency that occurrence of a connection failure is more easily suppressed.

In the present disclosure, the term “connection” means that a semiconductor element and a substrate, or semiconductor elements are electrically connected to each other via a protruding electrode and an electrode pad.

Hereinafter, one embodiment of the method for manufacturing a semiconductor device of the present disclosure will be described in detail with reference to the drawings. In the following description, the same or corresponding portions are denoted by the same reference numerals, and redundant description is omitted. Unless otherwise specified, the positional relationship such as up, down, left, and right is based on the positional relationship illustrated in the drawings. The dimensional ratios in the drawings are not limited to the illustrated ratios.

### First Embodiment

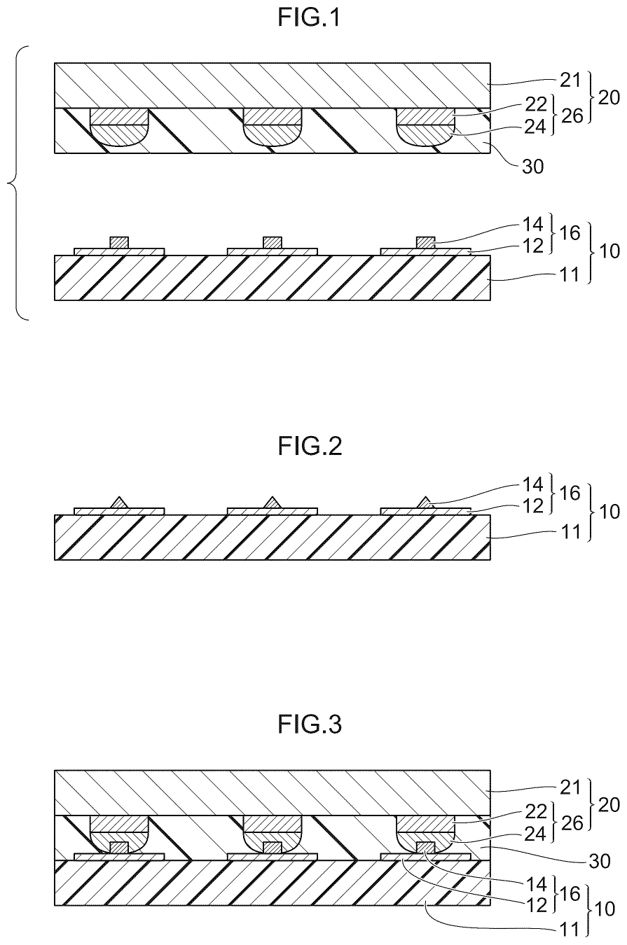

A method for manufacturing a semiconductor device according to a first embodiment of the present disclosure will be described with reference to FIGS. 1 to 4. In the method for manufacturing a semiconductor device according to the first embodiment, one semiconductor element is layered in a thickness direction of a substrate.

FIG. 1 is a cross-sectional view illustrating cross-sections of a substrate 10 and a semiconductor element 20 used in the method for manufacturing a semiconductor device according to the first embodiment. FIG. 1 illustrates a state before the semiconductor element 20 and the substrate 10 are connected.

The semiconductor element 20 has a semiconductor element body 21 and a plurality of protruding electrodes 26 each including a pillar 22 disposed on one surface of the semiconductor element body 21 and a solder layer 24 provided at a distal end portion of the pillar 22.

The substrate 10 has a substrate body 11 and a plurality of electrode pads 16 each having an electrode pad body 12 disposed on a surface facing a surface of the semiconductor element 20 in the substrate body 11 on which the protruding electrode 26 is provided and a metal protruding portion 14 provided on a surface of the electrode pad body 12.

A resin film 30 is disposed on one surface (that is, a surface facing the substrate 10) of the semiconductor element 20, and the resin film 30 is interposed between the semiconductor element 20 and the substrate 10.

The type of the semiconductor element body 21 is not particularly limited, and an elemental semiconductor composed of the same type of element such as silicon or germanium, a compound semiconductor such as gallium arsenide or indium phosphide, and the like, can be used. A chip (die) itself that is not packaged with a resin or the like, a CSP that is packaged with a resin or the like, and a semiconductor package called BGA or the like, can also be exemplified.

The protruding electrode 26 is not particularly limited as long as it has the solder layer 24 at the distal end portion. In the first embodiment, the protruding electrode 26 is configured by a combination of the pillar 22 and the solder layer 24 provided at the distal end of the pillar 22, but the configuration of the protruding electrode 26 is not limited thereto.

An interval between the protruding electrodes 26 is not particularly limited, and is, for example, preferably from 1 μm to 100 μm, more preferably from 10 μm to 70 μm, and still more preferably from 30 μm to 50 μm.

A thickness of the solder layer 24 is not particularly limited, and is, for example, preferably from 0.1 μm to 50 μm, more preferably from 1 μm to 30 μm, and still more preferably from 5 μm to 20 μm. When the thickness of the solder layer 24 is 0.1 μm or more, an amount of extension of the metal protruding portion 14 into the solder layer 24 can be sufficiently ensured, and the temporary fixing force is less likely to be small. Therefore, there is a tendency that misalignment of the semiconductor element 20 in a later step is less likely to occur. When the thickness of the solder layer 24 is 50 μm or less, there is a tendency that the processing time for melting the solder layer 24 by heating to connect the substrate 10 and the semiconductor element 20 is less likely to be prolonged. Further, there is a tendency that an electrical short circuit between adjacent electrodes is less likely to occur when the substrate 10 and the semiconductor element 20 are connected.

An average height of the pillar 22 is not particularly limited, and is, for example, preferably from 20 μm or less, more preferably from 0.1 μm to 20 μm, and still more preferably from 2 μm to 10 μm. When the average height of the pillar 22 is 20 μm or less, there is a tendency that the height of the entire semiconductor device when the semiconductor elements 20 are layered can be suppressed. In a case in which the average height of the pillar 22 is 20 μm or less, a variation in height of each of the pillars 22 is likely to be relatively large. In the method for manufacturing a semiconductor device of the present disclosure, since the solder layer 24 provided at the distal end of the protruding electrode 26 and the distal end of the metal protruding portion 14 are brought into contact with each other, the distal end of the metal protruding portion 14 extends into the solder layer 24 so that the variation in height of each of the pillars 22 can be absorbed, and there is a tendency that the connection reliability is further improved.

In a case in which the protruding electrode 26 has a configuration having the pillar 22 and the solder layer 24 provided at the distal end of the pillar 22, the pillar 22 having a metal layer mainly composed of gold, silver, copper, tin, nickel, or the like may be formed, for example, by plating. The metal layer configuring the pillar 22 may contain a single component, or may contain a plurality of components. The metal layer may have a single-layer structure, or may have a multi-layer structure in which a plurality of metal layers are layered. As a material of the pillar 22, copper can be preferably used because of a low electric resistance and relatively high corrosion resistance.

As a solder material configuring the solder layer 24, tin-silver-based solder, tin-lead-based solder, tin-bismuth-based solder, tin-copper-based solder, gold-copper-based solder, tin-silver-copper-based solder, or the like can be used, and lead-free solder such as gold-copper-based solder, tin-copper-based solder, tin-bismuth-based solder, tin-silver-based solder, or tin-silver-copper-based solder can be preferably used from the viewpoint of environmental issues and safety.

In the case of forming the solder layer 24 on the pillar 22 made of copper, from the viewpoint of improving connection reliability, a nickel layer may be formed between the pillar 22 made of copper and the solder layer 24 in order to suppress diffusion between metal components. In order to make it easy for the metal protruding portion 14 of the electrode pad 16 to extend into the solder layer 24, after the solder layer 24 is formed on the distal end portion of the pillar 22 by plating, printing, or the like, it is not necessary to subject the solder layer 24 to a heat treatment.

The type of the substrate body 11 is not particularly limited, and examples thereof include a wiring board in which conductor wiring including an electrode for connection is formed on an organic substrate including a fiber base material such as FR4 or FR5, a built-up type organic substrate not including a fiber base material, an organic film such as polyimide or polyester, a base material containing an inorganic material such as alumina, glass, or silicon, or the like. A circuit, a substrate electrode, or the like may be formed on the substrate body 11 by a method such as a semi-additive method or a subtractive method.

The substrate body 11 may be silicon (Si). A size, a thickness, or the like of a substrate made of silicon (Si) is not limited. Examples of the substrate made of silicon (Si) include a wafer having a surface on which conductor wiring including an electrode for connection is formed. Wiring, transistors, other electronic elements, through silicon vias (TSV), or the like may be formed on the substrate made of silicon (Si).

The electrode pad body 12 may be conductor wiring formed on the surface of the substrate body 11 by a method such as a semi-additive method or a subtractive method.

The metal protruding portion 14 may be formed on the surface of the electrode pad body 12 using photolithography.

In the case of forming the metal protruding portion 14 on the surface of the electrode pad body 12 using a photolithography technique, the metal protruding portion 14 can be formed through a process of carrying out application of a photosensitive photoresist onto the surface of the electrode pad body 12 on which a seed layer is left, exposure, development, plating, stripping of the photoresist, and etching of the seed layer. A method of forming the metal protruding portion 14 on the surface of the electrode pad body 12 is not limited to the method described above.

As the method of forming the metal protruding portion 14, in addition to the method of forming the metal protruding portion using photolithography, a method of welding a metal wire such as gold or copper on an electrode pad using a ball bonder, forming into a columnar shape, and cutting the column at a specific length, a method of forming the metal protruding portion using a 3D printer, a method of forming the metal protruding portion by cutting, or the like can also be used.

A material of the metal protruding portion 14 is not particularly limited, and various metals such as copper and nickel may be used. In the case of using copper as the material of the metal protruding portion 14, there is a tendency that the heat dissipation effect at the connecting portion between the substrate 10 and the semiconductor element 20 is improved and the connection resistance is decreased.

In order to ensure connection between the substrate 10 and the semiconductor element 20, the surface of the metal protruding portion 14 may be subjected to gold plating, nickel/gold plating, Organic Solderability Preservatives (OSP) treatment, or the like.

A shape of the metal protruding portion 14 is not particularly limited. Examples of the shape of the metal protruding portion 14 include columnar bodies such as a cylindrical column, a rectangular parallelepiped, and a triangular prism. The metal protruding portion 14 may have a shape in which at least two cylindrical columns, rectangular parallelepipeds, triangular prisms, or the like are overlapped in a height direction.

The distal end of the metal protruding portion 14 may have an acute angle. Examples of the metal protruding portion 14 with a distal end having an acute angle include, but are not limited to, cones such as a circular cone, a triangular pyramid, and a quadrangular pyramid, and a shape in which a cone is disposed on a columnar body. When the distal end of the metal protruding portion 14 has an acute angle, there is a tendency that biting of the resin film is more easily suppressed. FIG. 2 is a cross-sectional view illustrating a cross-section of a modification of the substrate 10 according to the first embodiment. In the substrate 10 illustrated in FIG. 2, the metal protruding portion 14 is configured as a cone.

Among the components configuring the resin film, an inorganic filler is exemplified as a component that is easily bitten between the protruding electrode and the electrode pad. When the distal end of the metal protruding portion 14 has an acute angle, even in the case of using a resin film having a high content ratio of the inorganic filler, there is a tendency that biting of the resin film is more easily suppressed. Therefore, when the metal protruding portion 14 with a distal end having an acute angle is used, there is a tendency that a content ratio of the inorganic filler in the resin film 30 can be increased. From such a viewpoint, the content ratio of the inorganic filler in the resin film 30 may be from 50% by mass to 90% by mass based on the total amount of the resin film 30.

Further, there are tendencies that the metal protruding portion 14 easily extends into the solder layer 24, the metal protruding portion 14 and the solder layer 24 of the protruding electrode 26 bite more favorably with each other, a strength against the external force during a reflow treatment increases, and misalignment of the semiconductor element 20 in a later step is less likely to occur.

The electrode pad 16 may have two or more metal protruding portions 14 on the surface of the electrode pad body 12. In a case in which two or more metal protruding portions 14 are provided on the surface, the shapes of the metal protruding portions 14 may be the same as or different from each other.

A value of a thickness of the solder layer 24 of the protruding electrode 26 is desirably larger than a value of a height of the metal protruding portion 14 in the electrode pad 16. As a result, the metal protruding portion 14 easily extends into the solder layer 24.

In a case in which the metal protruding portion 14 extends into the solder layer 24 as deeply as possible, the strength of the temporary fixing force can be increased, and there is a tendency that misalignment of the connecting portion can be further suppressed. An average height of the metal protruding portion 14 is not particularly limited, and is preferably from 0.1 μm to 50 μm, more preferably from 0.5 μm to 30 μm, and still more preferably from 1 μm to 10 μm, from the viewpoint that the amount of extension of the metal protruding portion 14 into the solder layer 24 can be increased and the viewpoint of industrial productivity. In order to improve the solder wettability at the time of forming a connection between the metal protruding portion 14 and the protruding electrode 26 by solder melting, a gold-containing layer containing gold as a main component can also be formed on the outermost surface of the metal protruding portion 14. The method of forming a gold-containing layer is not particularly limited, and a method such as plating or sputtering can be used.

The composition of the resin film 30 is not particularly limited, and may be a resin composition containing a thermoplastic resin, a thermosetting resin, an inorganic filler, or the like. The resin composition configuring the resin film 30 may contain a flux component for improving the connectivity between the protruding electrode and the electrode pad if necessary.

In a case in which the resin film 30 contains a thermoplastic resin, the thermoplastic resin preferably contains at least one selected from the group consisting of polyimide, polyamide, polycarbonate, polyacetal, polyphenylene ether, polybutylene terephthalate, polytetrafluoroethylene, polyphenylene sulfide, polysulfone, polyethersulfone, polyarylate, polyamideimide, polyetherimide, polyether ether ketone, an acrylic resin, a phenoxy resin, polyester, polyurethane, polybenzoxazole, and polybutadiene.

In a case in which the resin film 30 contains a thermosetting resin, the thermosetting resin preferably contains at least one selected from the group consisting of an epoxy resin, a polyamic acid, and a polyhydroxyamide. Here, polyimide is generated by a curing reaction of a polyamic acid. Polybenzoxazole is generated by a curing reaction of a polyhydroxyamide.

In a case in which the resin film 30 contains an inorganic filler, examples of the inorganic filler include insulating inorganic fillers such as glass, silica, alumina, titanium oxide, mica, and boron nitride, and conductive inorganic fillers such as carbon black. Among them, it is preferable to use an insulating inorganic filler selected from silica, alumina, titanium oxide, or boron nitride, or an insulating inorganic filler selected from silica, alumina, or boron nitride. The inorganic filler may be a whisker, and examples thereof include aluminum borate, aluminum titanate, zinc oxide, calcium silicate, magnesium sulfate, and boron nitride. These inorganic fillers can be used singly or in combination of two or more kinds thereof.

The resin film 30 may contain a resin filler (organic filler). In a case in which the resin film 30 contains a resin filler, the inorganic filler may be used in combination or is not necessarily used in combination. Examples of the resin filler include a polyurethane resin, a polyimide resin, a methyl methacrylate resin, and a methyl methacrylate-butadiene-styrene copolymer resin (MBS). These resin fillers can be used singly or in combination of two or more kinds thereof.

The inorganic filler and the resin filler may have physical properties appropriately adjusted by a surface treatment.

The resin film 30 preferably contains an epoxy resin from the viewpoint of excellent balance among various properties such as workability, formability, electrical properties, moisture resistance, heat resistance, mechanical properties, and adhesiveness.

Hereinafter, a case in which the resin film 30 contains an epoxy resin will be described.

The epoxy resin is not particularly limited as long as it has two or more epoxy groups in the molecule. As the epoxy resin, various polyfunctional epoxy resins such as a bisphenol A type epoxy resin, a bisphenol F type epoxy resin, a naphthalene type epoxy resin, a phenol novolac type epoxy resin, a cresol novolac type epoxy resin, a phenol aralkyl type epoxy resin, a biphenyl type epoxy resin, a triphenylmethane type epoxy resin, and a dicyclopentadiene type epoxy resin can be used. These can be used singly or in combination of two or more kinds thereof.

A weight average molecular weight of the epoxy resin is not particularly limited, and is preferably less than 10000.

In the present disclosure, the weight average molecular weight is obtained by performing measurement by gel permeation chromatography (GPC) method and converting measurement results using a calibration curve of standard polystyrene. GPC conditions are as follows.

### —GPC Conditions—

Pump: Hitachi L-6000 type (manufactured by Hitachi, Ltd.)
Columns: The following three columns in total
Gelpack GL-R420
Gelpack GL-R430
Gelpack GL-R440
(all manufactured by Showa Denko Materials Co., Ltd., trade names)
Eluent: Tetrahydrofuran
Measurement temperature: 25° C.
Flow rate: 2.05 mL/min
Detector: Hitachi L-3300 type RI (manufactured by Hitachi, Ltd.)

A content ratio of the epoxy resin is, for example, from 5% by mass to 75% by mass, preferably from 10% by mass to 50% by mass, and more preferably from 15% by mass to 35% by mass, based on the total amount of the resin film 30.

In a case in which the resin film 30 contains an epoxy resin, the resin film 30 may contain a curing agent.

Examples of the curing agent include a phenol resin-based curing agent, an acid anhydride-based curing agent, an amine-based curing agent, an imidazole-based curing agent, and a phosphine-based curing agent. From the viewpoint of exhibiting fluxing activity to prevent generation of an oxidized film on the protruding electrode 26 or the electrode pad 16 and improving connection reliability and insulation reliability, the curing agent preferably contains at least one selected from a phenol resin-based curing agent, an acid anhydride-based curing agent, an amine-based curing agent, or an imidazole-based curing agent. Each curing agent will be described below.

The phenol resin-based curing agent is not particularly limited as long as it has two or more phenolic hydroxyl groups in the molecule, and examples thereof include a phenol novolac resin, a cresol novolac resin, a phenol aralkyl resin, a cresol naphthol formaldehyde polycondensate, a triphenylmethane-type polyfunctional phenol resin, and various polyfunctional phenol resins. These can be used singly or as a mixture of two or more kinds thereof.

An equivalent ratio of the phenol resin-based curing agent with respect to the epoxy resin (phenolic hydroxyl group/epoxy group, molar ratio) is preferably from 0.3 to 1.5, more preferably from 0.4 to 1.0, and still more preferably from 0.5 to 1.0, from the viewpoint of favorable curability, adhesiveness, and storage stability. When the equivalent ratio is 0.3 or more, there is a tendency that curability is improved to improve adhesive strength, and when the equivalent ratio is 1.5 or less, there are tendencies that an unreacted phenolic hydroxyl group does not excessively remain, water absorption is suppressed to be low, and the insulation reliability of the semiconductor device is improved. When the equivalent ratio is from 0.3 to 1.5, the gelling time is easily adjusted to an appropriate range.

Examples of the acid anhydride-based curing agent include methylcyclohexane tetracarboxylic dianhydride, trimellitic anhydride, pyromellitic anhydride, benzophenone tetracarboxylic dianhydride, and ethylene glycol bisanhydrotrimellitate. These can be used singly or as a mixture of two or more kinds thereof.

An equivalent ratio of the acid anhydride-based curing agent with respect to the epoxy resin (acid anhydride group/epoxy group, molar ratio) is preferably from 0.3 to 1.5, more preferably from 0.4 to 1.0, and still more preferably from 0.5 to 1.0, from the viewpoint of favorable curability, adhesiveness, and storage stability. When the equivalent ratio is 0.3 or more, there is a tendency that curability is improved to improve adhesive strength, and when the equivalent ratio is 1.5 or less, there are tendencies that an unreacted acid anhydride does not excessively remain, water absorption is suppressed to be low, and the insulation reliability of the semiconductor device is improved. When the equivalent ratio is from 0.3 to 1.5, the gelling time is easily adjusted to an appropriate range.

As the amine-based curing agent, for example, dicyandiamide can be used.

An equivalent ratio of the amine-based curing agent with respect to the epoxy resin (amino group/epoxy group, molar ratio) is preferably from 0.3 to 1.5, more preferably from 0.4 to 1.0, and still more preferably from 0.5 to 1.0, from the viewpoint of favorable curability, adhesiveness, and storage stability. When the equivalent ratio is 0.3 or more, there is a tendency that curability is improved to improve adhesive strength, and when the equivalent ratio is 1.5 or less, there are tendencies that an unreacted amine does not excessively remain, and the insulation reliability of the semiconductor device is improved. When the equivalent ratio is from 0.3 to 1.5, the gelling time is easily adjusted to an appropriate range.

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adducts, 2-phenylimidazole isocyanuric acid adducts, 2-phenyl-4,5-dihydroxymethylimidazole, 2-phenyl-4-methyl-5-hydroxymethylimidazole, and adducts of epoxy resins and imidazoles. From the viewpoint of excellent curability, storage stability, and connection reliability, the imidazole-based curing agent may be selected from 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adducts, 2-phenylimidazole isocyanuric acid adducts, 2-phenyl-4,5-dihydroxymethylimidazole, and 2-phenyl-4-methyl-5-hydroxymethylimidazole. These can be used singly or in combination of two or more kinds thereof. Microcapsules containing them can also be used as a latent curing agent.

A content of the imidazole-based curing agent is preferably from 0.1 parts by mass to 20 parts by mass, more preferably from 0.1 parts by mass to 10 parts by mass, and still more preferably from 3.2 parts by mass to 5.5 parts by mass, with respect to 100 parts by mass of the epoxy resin. When the content of the imidazole-based curing agent is 0.1 parts by mass or more, there is a tendency that the curability of the resin film 30 is improved, and when the content thereof is 20 parts by mass or less, there is a tendency that a connection failure is less likely to occur. When the content of the imidazole-based curing agent is from 0.1 parts by mass to 20 parts by mass, the gelling time is easily adjusted to an appropriate range.

Examples of the phosphine-based curing agent include triphenylphosphine, tetraphenylphosphonium tetraphenylborate, tetraphenylphosphonium tetra(4-methylphenyl) borate, and tetraphenylphosphonium (4-fluorophenyl) borate.

A content of the phosphine-based curing agent is preferably from 0.1 parts by mass to 10 parts by mass and more preferably from 0.1 parts by mass to 5 parts by mass, with respect to 100 parts by mass of the epoxy resin. When the content of the phosphine-based curing agent is 0.1 parts by mass or more, there is a tendency that the curability of the resin film 30 is improved, and when the content thereof is 10 parts by mass or less, there is a tendency that a connection failure is less likely to occur.

The phenol resin-based curing agent, the acid anhydride-based curing agent, and the amine-based curing agent each can be used singly or as a mixture of two or more kinds thereof. The imidazole-based curing agent and the phosphine-based curing agent each may be used singly, or each may be used together with the phenol resin-based curing agent, the acid anhydride-based curing agent, or the amine-based curing agent.

The resin film 30 may contain a fluxing agent. The fluxing agent is preferably a compound (dicarboxylic acid) having two carboxy groups. A compound having two carboxy groups is difficult to volatilize even at a high temperature at the time of connection as compared with a compound (monocarboxylic acid) having one carboxy group, which can further suppress generation of voids. When a compound having two carboxy groups is used, as compared with the case of using a compound having three or more carboxy groups, an increase in viscosity of the resin film 30 during storage, connection work, and the like can be further suppressed. As a result, the connection reliability of the semiconductor device can be further improved.

As the fluxing agent, for example, a compound in which an electron-donating group is substituted at the 2-position of a dicarboxylic acid selected from succinic acid, glutaric acid, adipic acid, pimelic acid, suberic acid, azelaic acid, sebacic acid, undecanedioic acid, or dodecanedioic acid, can be used.

A melting point of the fluxing agent is preferably 150° C. or lower, more preferably 140° C. or lower, and still more preferably 130° C. or lower. Such a fluxing agent sufficiently exhibits fluxing activity before a curing reaction between the epoxy resin and the curing agent occurs. Therefore, according to the resin film 30 containing such a fluxing agent, a semiconductor device further excellent in connection reliability can be realized. The fluxing agent is preferably a solid at room temperature, and the melting point of the fluxing agent is preferably 25° C. or higher and more preferably 50° C. or higher. The melting point of the fluxing agent can be measured by, for example, an apparatus in which a capillary tube filled with a sample is attached to a double tube thermometer and heated in a warm bath.

A content ratio of the fluxing agent is preferably from 0.5% by mass to 10% by mass and more preferably from 0.5% by mass to 5% by mass, based on the total amount of the resin film 30.

The resin film 30 may further contain a polymer component.

The polymer component is composed of a polymer different from the epoxy resin. Examples of such a polymer component include a phenoxy resin, polyimide, polyamide, polycarbodiimide, cyanate ester, an acrylic resin, polyester, polyethylene, polyethersulfone, polyetherimide, polyvinyl acetal, polyurethane, and acrylic rubber. From the viewpoint of excellent heat resistance and film formability, the polymer component is preferably a phenoxy resin, polyimide, acrylic rubber, cyanate ester, and polycarbodiimide, and is more preferably a phenoxy resin, polyimide, and acrylic rubber. These polymer components can be used singly or as a mixture or copolymer of two or more kinds thereof.

A weight average molecular weight of the polymer component is not particularly limited, and is preferably 10000 or more. In this case, the resin film 30 containing a polymer component is further excellent in heat resistance and film formability.

The weight average molecular weight of the polymer component is preferably 30000 or more, more preferably 40000 or more, and still more preferably 50000 or more, from the viewpoint that favorable film formability is imparted to the resin film 30 singly and the shape of the resin film 30 is easily maintained to efficiently manufacture a semiconductor device.

In a case in which the resin film 30 contains a polymer component having a weight average molecular weight of 10000 or more, a ratio Ca/Cd (mass ratio) of a content Ca of the epoxy resin with respect to a content Cd of the polymer component having a weight average molecular weight of 10000 or more is preferably from 0.01 to 5, more preferably from 0.05 to 3, and still more preferably from 0.1 to 2. When the ratio Ca/Cd is 0.01 or more, favorable curability and adhesive strength can be obtained. When the ratio Ca/Cd is 5 or less, in the resin film 30, more favorable film formability can be obtained.

In a case in which the resin film 30 contains an inorganic filler, specific examples of the inorganic filler are as described above.

A content ratio of the inorganic filler is preferably from 10% by mass to 80% by mass and more preferably from 15% by mass to 60% by mass, based on the total amount of the resin film 30, from the viewpoint of adjusting the minimum melt viscosity of the resin film 30 to an appropriate range.

The resin film 30 may further contain other components such as an ion trapper, an antioxidant, a silane coupling agent, a titanium coupling agent, and a leveling agent. These may be used singly, or in combination of two or more kinds thereof. The blending amount of them may be appropriately adjusted so that the effect of each additive is exhibited.

An average thickness of the resin film 30 is not particularly limited, and can be appropriately set in view of a gap space volume between the substrate 10 and the semiconductor element 20 when the substrate 10 and the semiconductor element 20 are connected to obtain a semiconductor device, a volume of a fillet formed by leaking a component of the resin film 30 to the periphery of the semiconductor element 20, and the like.

For example, the average thickness of the resin film 30 may be set so that a total value of the average height of the pillar 22 and the average height of the metal protruding portion 14 is smaller than the average thickness of the resin film 30.

The average thickness of the resin film 30 is, for example, preferably from 1 μm to 100 μm, more preferably from 5 μm to 70 μm, and still more preferably from 10 μm to 50 μm.

A viscosity of the resin film 30 at 130° C. is preferably from 500 mPa·s to 4000 mPa·s, more preferably from 700 mPa·s to 3000 mPa·s, and still more preferably from 1000 mPa·s to 2000 mPa·s, from the viewpoint of fluidity.

The viscosity of the resin film 30 at 130° C. is measured by a rheometer AR2000 (manufactured by TA Instruments, aluminum cone 40 mm, shear rate 32.5/sec).

The resin film 30 can be produced by a method of applying, on a base material film, a resin varnish containing components configuring the resin film 30, such as an epoxy resin, a curing agent, an inorganic filler, and a fluxing agent, and if necessary, an organic solvent and other components, to form a coating film, and drying the coating film.

The resin varnish is prepared by mixing components configuring the resin film 30, such as an epoxy resin, a curing agent, an inorganic filler, and a fluxing agent, with an organic solvent, and dissolving or dispersing them by stirring or kneading. The resin varnish is applied onto a base material film subjected to a releasing treatment, for example, using a knife coater, a roll coater, an applicator, a die coater, or a comma coater. Thereafter, the organic solvent is reduced from the coating film of the resin varnish by heating, that is, the coating film is dried to form the resin film 30 on the base material film. The resin film 30 may be formed on a semiconductor wafer by a method of forming a film of a resin varnish on a semiconductor wafer or the like by a method such as spin coating, and then drying the coating film.

The organic solvent used for preparing the resin varnish is preferably those having a property of uniformly dissolving or dispersing each component, and examples thereof include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combination of two or more kinds thereof. In preparation of the resin varnish, stirring and kneading can be performed, for example, using a stirrer, a stone mill, a triple roll, a ball mill, a bead mill, or a homodisper.

The base material film is not particularly limited as long as it has heat resistance capable of withstanding heating conditions when the organic solvent is volatilized, and examples thereof include polyolefin films such as polypropylene films and polymethylpentene films, polyester films such as polyethylene terephthalate films and polyethylene naphthalate films, and polyimide films, and polyetherimide films. The base material film is not limited to a single-layer film composed of these films, and may be a multilayer film composed of two or more materials.

Heating performed to volatilize the organic solvent from the resin varnish after application may be, specifically, heating at from 50° C. to 200° C. for from 0.1 minutes to 90 minutes. The organic solvent may be removed until the residual amount becomes 1.5% by mass or less as long as the suppression of void generation and viscosity adjustment are not substantially affected.

A method of disposing the resin film 30 on the surface of the semiconductor element 20 facing the substrate 10 is not particularly limited.

For example, a semiconductor element 20 attached with the resin film 30 may be used, which is obtained by, in a wafer size state before dicing, disposing the resin film 30 so as to cover the protruding electrode 26 on a surface corresponding to a surface of the semiconductor element 20 on which the resin film 30 is disposed, and then performing dicing.

In FIG. 1, although the resin film 30 is disposed on a surface of the semiconductor element 20 facing the substrate 10, the resin film 30 may be disposed on a surface of the substrate 10 facing the semiconductor element 20.

A place where the resin film 30 is disposed may be appropriately selected in consideration of the arrangement of the protruding electrode 26 in the semiconductor element 20 or the electrode pad 16 in the substrate 10, or the layout situation of a solder resist that may be applied to the substrate 10.

From the viewpoint of ensuring the embedding properties of the irregularities of the protruding electrode 26, the electrode pad 16, and the like, and the film thickness uniformity of a layer derived from the resin film 30, the resin film 30 is preferably disposed on a surface of the semiconductor element 20 facing the substrate 10.

In order to dispose the resin film 30 on the semiconductor element 20 or the substrate 10, hot roll lamination, diaphragm lamination, hot plate lamination, or the like can be used, and a method using one of these singly or a plurality of these in combination may be selected. In order to improve and stabilize the lamination property, the lamination processing itself may be performed under a reduced pressure environment.

Next, in the contact step, the protruding electrode 26 and the metal protruding portion 14 provided on the electrode pad 16 facing the protruding electrode 26 are aligned. In the contact step, as illustrated in FIG. 3, pressure is applied in a state in which the protruding electrode 26 and the electrode pad 16 having the metal protruding portion 14 face each other, and the metal protruding portion 14 of the electrode pad 16 is extended into the solder layer 24 of the protruding electrode 26 to temporarily mount the semiconductor element 20 on the substrate 10. The temporal mounting of the semiconductor element 20 on the substrate 10 can be performed using a flip-chip bonder or the like. By temporarily mounting the semiconductor element 20 on the substrate 10 with the resin film 30 interposed therebetween, there is a tendency that occurrence of misalignment of the semiconductor element 20 is suppressed.

The magnitude of the pressure applied at the time of pressurization is not particularly limited. Similarly to general flip-chip mounting processes, the pressure can be set in consideration of the number of protruding electrode 26, a variation in height of the protruding electrodes 26, the deformation amount of the protruding electrode 26 or the wiring on the substrate 10 due to the pressurization, and the like. Specifically, for example, the pressure is preferably set so that a load received per one protruding electrode is about from 1 gf (0.0098 N) to 20 gf (0.196 N). For example, the pressure is preferably set so that a load applied to one semiconductor element 20 is about from 5 N to 200 N.

In a case in which the load received per one protruding electrode is 0.0098 N or more or the load applied to the semiconductor element 20 is 5 N or more, there are tendencies that the temporary fixing force of the semiconductor element 20 to the substrate 10 is sufficient, and misalignment of the semiconductor element 20 in a later step is less likely to occur. In a case in which the load received per one protruding electrode is 0.196 N or less or the load applied to the semiconductor element 20 is 200 N or less, there is a tendency that occurrence of damage to the semiconductor element 20 due to an excessively large load is suppressed.

When the solder layer 24 and the metal protruding portion 14 are pressurized in contact with each other, at least one of the substrate 10 or the semiconductor element 20 may be heated. From the viewpoint of productivity, it is preferable to bring the solder layer 24 and the distal end of the metal protruding portion 14 into contact with each other with the resin film 30 interposed therebetween while heating is performed under a condition of a melting temperature of solder configuring the solder layer 24 or lower, it is more preferable to bring them into contact with each other at a temperature of 210° C. or lower, and it is still more preferable to bring them into contact with each other at a temperature of 200° C. or lower.

When the solder layer 24 and the metal protruding portion 14 are pressurized in contact with each other, a gap may be generated in at least one of a region between the resin film 30 and the semiconductor element 20 or a region between the resin film 30 and the substrate 10. If the gap remains as it is, this remains as a void in the semiconductor device. The gap can be eliminated by pressurizing and compressing the resin film 30.

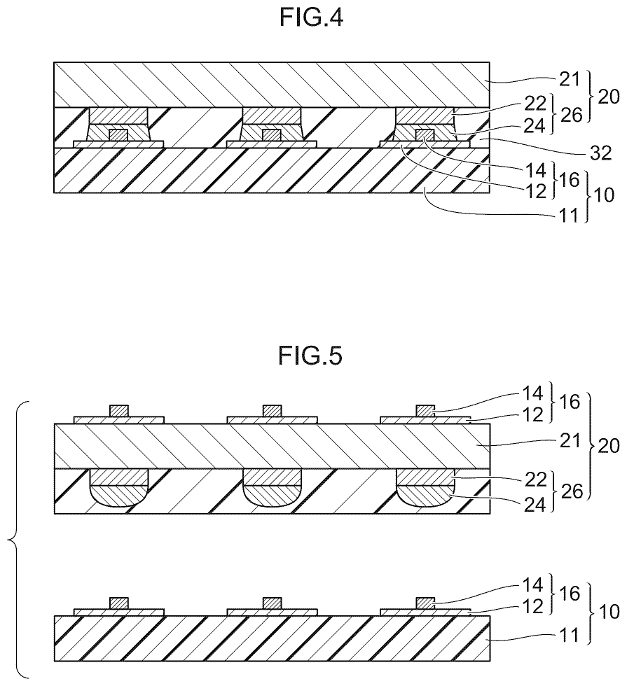

Thereafter, in the connecting step, in a state in which the semiconductor element 20 is layered and temporarily mounted on the substrate 10, the solder layer 24 is melted using a heating device represented by reflow, and the protruding electrode 26 of the semiconductor element 20 and the electrode pad 16 having the metal protruding portion 14 of the substrate 10 are connected by solder, thereby connecting the substrate 10 and the semiconductor element 20. Through the above steps, a semiconductor device in which the metal protruding portion 14 extends into the solder layer 24 as illustrated in FIG. 4 is manufactured. In the case of using a resin film containing a thermosetting resin as the resin film 30, the resin film 30 is cured with solder connection to form a cured resin layer 32 between the semiconductor element 20 and the substrate 10.

The heating device is not limited to a reflow furnace, and a hot plate, an oven, or the like can be used.

A heating temperature in the connecting step is preferably a temperature at which solder melts, more preferably 220° C. or higher, and still more preferably 230° C. or higher.

The connecting step is preferably performed in a nitrogen atmosphere in order to prevent oxidation of the protruding electrode 26 and the electrode pad 16 having the metal protruding portion 14.

The connecting step may be performed while pressurizing. By connecting the substrate 10 and the semiconductor element 20 while pressurizing, there is a tendency that biting of the resin film 30 is more easily suppressed. The pressurization conditions are not particularly limited.

### Second Embodiment

A method for manufacturing a semiconductor device according to a second embodiment of the present disclosure will be described with reference to FIGS. 5 to 7. In the method for manufacturing a semiconductor device according to the second embodiment, four semiconductor elements are layered in a thickness direction of a substrate.

In the second embodiment, as illustrated in FIG. 5, the semiconductor element body 21 includes the electrode pad 16 having the metal protruding portion 14 on the surface of the electrode pad 16, the electrode pad 16 being provided on a surface of the semiconductor element body 21 at an opposite side from a surface on which the protruding electrode 26 having the solder layer 24 at the distal end portion is provided.

In the semiconductor element 20 according to the second embodiment, the protruding electrode 26 and the electrode pad 16 may be connected to each other by a TSV structure (not illustrated).

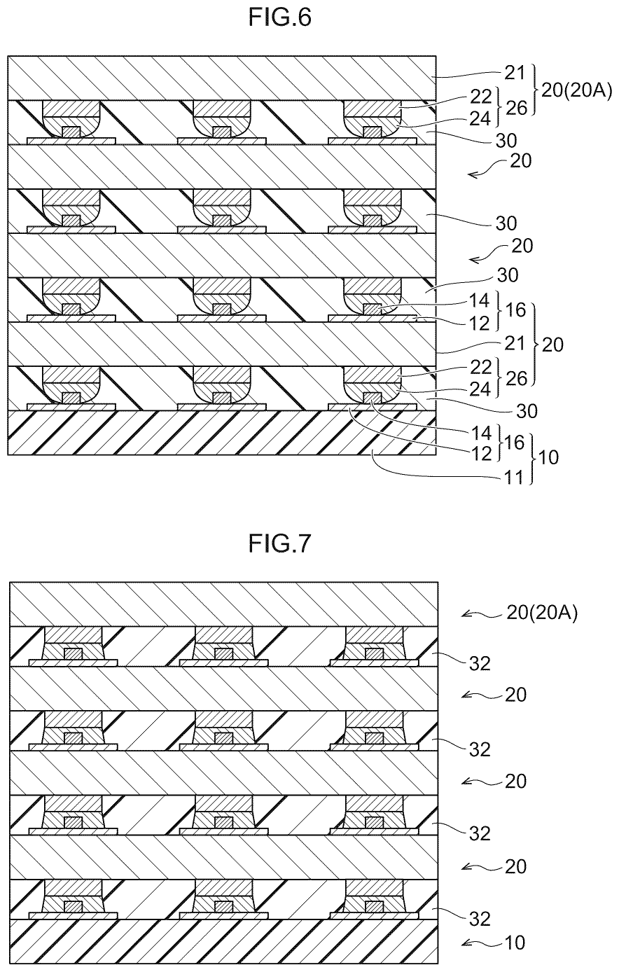

In the second embodiment, as illustrated in FIG. 6, a plurality of second semiconductor elements 20 are layered on the semiconductor element 20 layered on the substrate 10, by successively layering each of the plurality of second semiconductor elements 20 on the semiconductor element 20 layered on the substrate 10 such that the solder layer 24 in one semiconductor element 20 and the distal end of the metal protruding portion 14 of another semiconductor element 20 are brought into contact with each other in a state in which the resin film 30 is interposed between the one semiconductor element 20 and the other semiconductor element 20. Among the semiconductor elements layered on the substrate 10, an electrode pad is not necessarily provided on the semiconductor element 20 (semiconductor element 20A) farthest from the substrate 10.

Next, the solder layer 24 is melted by heating to collectively connect the substrate 10 and the plurality of second semiconductor elements 20, thereby manufacturing a semiconductor device in which the metal protruding portion 14 extends into the solder layer 24 as illustrated in FIG. 7. In the case of using a resin film containing a thermosetting resin as the resin film 30, the resin film 30 is cured with solder connection to form a cured resin layer 32 between the semiconductor element 20 and the substrate 10 and between the semiconductor elements 20.

The details of the semiconductor element, the substrate, and the resin film used in the method for manufacturing a semiconductor device according to the second embodiment, and the conditions for the contact step, the connecting step, and the other steps are the same as those in the case of the method for manufacturing a semiconductor device according to the first embodiment.

In the second embodiment, although the substrate 10 and the plurality of semiconductor elements 20 are collectively connected by heating, a semiconductor device can also be manufactured by individually repeating layering and connection of the substrate 10 and the semiconductor elements 20.

### <Substrate and Semiconductor Element>

A substrate of the present disclosure includes an electrode pad having a metal protruding portion with a distal end having an acute angle on a surface of the electrode pad. The details of the substrate of the present disclosure are as mentioned in the method for manufacturing a semiconductor device according to the first embodiment.

A semiconductor element of the present disclosure includes an electrode pad having a metal protruding portion with a distal end having an acute angle on a surface of the electrode pad. The details of the semiconductor element of the present disclosure are as mentioned in the method for manufacturing a semiconductor device according to the first embodiment and the second embodiment.

All publications, patent applications, and technical standards mentioned in this specification are herein incorporated by reference to the same extent as if each individual publication, patent application, or technical standard was specifically and individually indicated to be incorporated by reference.

Reference Signs List

| | |
|---|---|
| 10 | Substrate |
| 11 | Substrate body |
| 12 | Electrode pad body |
| 14 | Metal protruding portion |
| 16 | Electrode pad |
| 20 | Semiconductor element |
| 21 | Semiconductor element body |
| 22 | Pillar |
| 24 | Solder layer |
| 26 | Protruding electrode |
| 30 | Resin film |
| 32 | Cured resin layer |

1. A method for manufacturing a semiconductor device, comprising:
layering a semiconductor element, which includes a protruding electrode having a solder layer at a distal end portion of the protruding electrode, on a substrate, the substrate including an electrode pad having a metal protruding portion on a surface of the electrode pad, with a surface of the substrate on which the electrode pad is provided facing a surface of the semiconductor element on which the protruding electrode is provided, such that the solder layer in the semiconductor element and a distal end of the metal protruding portion in the substrate are brought into contact with each other in a state in which a resin film is interposed between the semiconductor element and the substrate; and
melting the solder layer by heating to connect the substrate and the semiconductor element.

2. The method for manufacturing a semiconductor device according to claim 1, wherein:
the semiconductor element layered on the substrate includes an electrode pad having a metal protruding portion on a surface of the electrode pad, the electrode pad being provided on a surface of the semiconductor element at an opposite side from the surface on which the protruding electrode is provided,
a plurality of second semiconductor elements, each including a protruding electrode having a solder layer at a distal end portion of the protruding electrode on one surface side and an electrode pad having a metal protruding portion on a surface of the protruding electrode on another surface side, are layered on the semiconductor element layered on the substrate, by successively layering each of the plurality of second semiconductor elements on the semiconductor element layered on the substrate such that a solder layer in one semiconductor element and a distal end of a metal protruding portion of another semiconductor element are brought into contact with each other in a state in which the resin film is interposed between the one semiconductor element and the other semiconductor element, and
the solder layer is melted by heating to collectively connect the substrate and the plurality of second semiconductor elements.

3. The method for manufacturing a semiconductor device according to claim 1, wherein the solder layer and the distal end of the metal protruding portion are brought into contact with each other with the resin film interposed therebetween while being heated under a condition of a melting temperature of solder configuring the solder layer or lower.

4. The method for manufacturing a semiconductor device according to claim 1, wherein the protruding electrode has a pillar and the solder layer provided at a distal end of the pillar, and a total value of an average height of the pillar and an average height of the metal protruding portion is smaller than an average thickness value of the resin film.

5. The method for manufacturing a semiconductor device according to claim 4, wherein the average height of the pillar is 20 μm or less.

6. The method for manufacturing a semiconductor device according to claim 1, wherein the distal end of the metal protruding portion has an acute angle.

7. The method for manufacturing a semiconductor device according to claim 1, wherein the resin film contains a thermosetting resin.

8. The method for manufacturing a semiconductor device according to claim 7, wherein the thermosetting resin contains at least one selected from the group consisting of an epoxy resin, a polyamic acid, and a polyhydroxyamide.

9. The method for manufacturing a semiconductor device according to claim 1, wherein the resin film contains a thermoplastic resin.

10. The method for manufacturing a semiconductor device according to claim 9, wherein the thermoplastic resin contains at least one selected from the group consisting of polyimide, polyamide, polycarbonate, polyacetal, polyphenylene ether, polybutylene terephthalate, polytetrafluoroethylene, polyphenylene sulfide, polysulfone, polyethersulfone, polyarylate, polyamideimide, polyetherimide, polyether ether ketone, an acrylic resin, a phenoxy resin, polyester, polyurethane, polybenzoxazole, and polybutadiene.

11. The method for manufacturing a semiconductor device according to claim 1, wherein the resin film contains an inorganic filler.

12. The method for manufacturing a semiconductor device according to claim 11, wherein a content ratio of the inorganic filler is from 10% by mass to 80% by mass based on a total amount of the resin film.

13. The method for manufacturing a semiconductor device according to claim 1, wherein a viscosity of the resin film at 130° C. is from 500 mPa·s to 4000 mPa·s.

14. A substrate, comprising an electrode pad having a metal protruding portion with a distal end having an acute angle on a surface of the electrode pad.

15. A semiconductor element, comprising an electrode pad having a metal protruding portion with a distal end having an acute angle on a surface of the electrode pad.
